(19) United States
(12) Patent Application Publication
(10) Pub. No.: US 2022/0050225 A1
(43) Pub. Date: Feb. 17, 2022

(54) METASURFACE PRIMARY LENS AND METASURFACE SECONDARY LENS, MANUFACTURING METHOD THEREOF, AND OPTICAL SYSTEM

(71) Applicant: SOUTHERN UNIVERSITY OF SCIENCE AND TECHNOLOGY, Shenzhen (CN)

(72) Inventors: Guixin Li, Shenzhen (CN); Xuan Liu, Shenzhen (CN); Junhong Deng, Shenzhen (CN); Jinghui Li, Shenzhen (CN); Xing Cheng, Shenzhen (CN)

(21) Appl. No.: 17/278,865

(22) PCT Filed: Nov. 22, 2018
(86) PCT No.: PCT/CN2018/116927

§ 371 Date: Mar. 23, 2021

(30) Foreign Application Priority Data
Jul. 23, 2018 (CN) 201810814042.7

(51) Int. Cl. G02B 1/00; G02B 5/08; G03F 7/00; G03F 7/16; G03F 7/20

(52) U.S. Cl. CPC G02B 1/002; G02B 5/0858; G03F 7/2037; G03F 7/162; G03F 7/0005

(57) ABSTRACT

Provided are a metasurface primary mirror, a metasurface secondary mirror, a method for manufacturing a metasurface primary mirror, a method for manufacturing a metasurface secondary mirror, and an optical system. The metasurface primary mirror, manufactured by using the method for manufacturing a metasurface primary mirror, includes a transparent substrate which includes a primary mirror metasurface pattern on the transparent substrate. The primary mirror metasurface is configured to satisfy a primary mirror phase distribution such that incident light reflected by a metasurface secondary mirror onto the metasurface primary mirror is reflected and focused.

This application claims priority to Chinese Patent Application No. 201810814042.7 filed Jul. 23, 2018 and entitled “Metasurface primary lens, metasurface secondary lens, method for manufacturing primary lens, method for manufacturing secondary lens, and optical system”, the disclosure of which is incorporated herein by reference in its entirety.

### TECHNICAL FIELD

The present disclosure relates to the technical field of metasurfaces, for example, to a metasurface primary mirror, a metasurface secondary mirror, a method for manufacturing a metasurface primary mirror, a method for manufacturing a metasurface secondary mirror, and an optical system.

### BACKGROUND

Refractive lenses play an irreplaceable role in focusing and imaging systems, and reflective lenses with each composed of multiple mirrors also have essential applications in microscopes, telescopes, cameras and infrared imaging devices. In order to observe and shoot objects more conveniently, it is often required that the objects and images are located on two sides of the lens. For lenses in the related art, whether reflective, refractive or hybrid thereof, effective phase tuning and wavefront shaping depend on consecutive geometric curvatures of surfaces of elements. In order to obtain high-quality lenses, manufacturing processes such as severe grinding and polishing are required. Therefore, lenses in the related art are inevitably bulky and expensive to manufacture, making it difficult to achieve miniaturization, integration and low-cost mass production.

An effective solution of using a metasurface is thus provided in the related art. The metasurface is an interface formed by subwavelength metasurface functional units with spatial changes. The metasurface functional units can be carefully designed so that the polarization, amplitude and phase of electromagnetic waves can be effectively controlled at a subwavelength scale. Electromagnetic functional elements that are more compact, lighter and less lossy can be achieved with the metasurface due to the two-dimensional properties of the metasurface. Moreover, the manufacturing process of the metasurface is compatible with the complementary metal-oxide-semiconductor technology in the related art and is easier to be integrated into an optoelectronic technology. Planar elements designed based on metasurfaces are widely applied, for example, in holographic imaging, polarization conversion, spin-orbit angular momentum for generating light, abnormal reflection/refraction, and the like. Among the precision optical elements based on metasurfaces, the most attractive and promising one is a planar lens which may be used as a single lens, used for forming a lens group, or even combined into other more complex optical systems. The metasurface lens makes refractive optical elements light, thin, compact and easy to integrate, and can play a more important role in ultra-small optical devices having more advanced functions. With the flourishing trend of metasurface lenses, almost all attention has been focused on planar transmissive lenses based on refractive metasurfaces, while planar transmissive lenses based on reflective metasurfaces are rarely concerned. Although reflective metasurfaces exist, a single reflective element cannot form an effective transmissive lens. For many optical devices, the planar transmissive lenses based on reflective metasurfaces are as important as the planar transmissive lenses based on refractive metasurfaces. Moreover, in telescopes and a large number of infrared systems, the design of a reflective transmissive focusing system cannot be replaced.

### SUMMARY

The present disclosure provides a metasurface primary mirror, a metasurface secondary mirror, a method for manufacturing a metasurface primary mirror, a method for manufacturing a metasurface secondary mirror, and an optical system, which can achieve the design of applying a reflective metasurface to a transmissive lens and solve the issues of being severe in manufacturing process, heavy in weight, large in volume and difficult in miniaturization and integration of a reflective objective in the related art, beneficial to mass production with low cost.

An embodiment provides a method for manufacturing a metasurface primary mirror. The method includes that: a transparent substrate is provided; and a primary mirror metasurface functional unit pattern satisfying a primary mirror phase distribution is formed on the transparent substrate such that incident light reflected by a metasurface secondary mirror onto the metasurface primary mirror is reflected and focused.

An embodiment provides a metasurface primary mirror manufactured by using the preceding method for manufacturing a metasurface primary mirror. The metasurface primary mirror includes: a transparent substrate; and a primary mirror metasurface functional unit pattern located on the transparent substrate, where the primary mirror metasurface functional unit pattern is configured to satisfy a primary mirror phase distribution, such that incident light reflected by a metasurface secondary mirror onto the metasurface primary mirror is reflected and focused.

An embodiment provides a method for manufacturing a metasurface secondary mirror. The method includes that: a transparent substrate is provided; and a secondary mirror metasurface functional unit pattern satisfying a secondary mirror phase distribution is formed on the transparent substrate, such that incident light incident on the metasurface secondary mirror is reflected onto a metasurface primary mirror and is reflected and focused by the metasurface primary mirror.

An embodiment provides a metasurface secondary mirror manufactured by using the preceding method for manufacturing a metasurface secondary mirror. The metasurface secondary mirror includes: a transparent substrate; and a secondary mirror metasurface functional unit pattern located on the transparent substrate, where the secondary mirror metasurface functional unit pattern is configured to satisfy a secondary mirror phase distribution, such that incident light incident on the metasurface secondary mirror is reflected onto a metasurface primary mirror and is reflected and focused by the metasurface primary mirror.

An embodiment provides an optical system including the preceding metasurface primary mirror and the preceding metasurface secondary mirror.

### BRIEF DESCRIPTION OF DRAWINGS

FIG. 1 is a side view of a reflective objective in the related art;

FIG. 2 is a schematic diagram illustrating that a planar metasurface mirror reflects incident light according to an embodiment;

FIG. 3 is a structure view of a metasurface functional unit according to an embodiment;

FIG. 4 is a side view of a planar reflective metasurface objective according to an embodiment;

FIG. 5 is a top view of a metasurface primary mirror according to an embodiment;

FIG. 6 is a top view of a metasurface secondary mirror according to an embodiment;

FIG. 7 is a flowchart of a method for manufacturing a metasurface primary mirror according to an embodiment;

FIG. 8 is a flowchart of another method for manufacturing a metasurface primary mirror according to an embodiment;

FIGS. 9 to 13 are side views of the metasurface primary mirror corresponding to multiple flows of the method for manufacturing a metasurface primary mirror of FIG. 8;

FIG. 14 is a flowchart of a method for manufacturing a metasurface secondary mirror according to an embodiment;

FIG. 15 is a flowchart of another method for manufacturing a metasurface secondary mirror according to an embodiment; and

FIGS. 16 to 21 are side views of the metasurface secondary mirror corresponding to multiple flows of the method for manufacturing a metasurface secondary mirror of FIG. 15.

### DETAILED DESCRIPTION

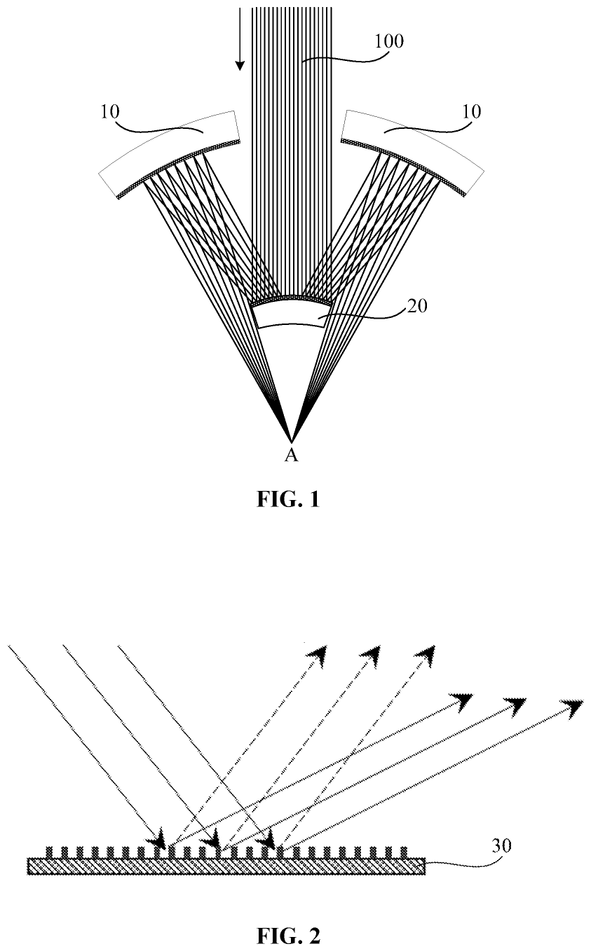

FIG. 1 is a side view of a reflective objective in the related art. As shown in FIG. 1, the reflective objective includes a curved primary mirror 10 and a curved secondary mirror 20. The reflective objective is usually a Schwarzschild reflective objective. That is, the curved primary mirror 10 and the curved secondary mirror 20 are spherical mirrors having a common spherical center, and the curved secondary mirror 20 is aligned with the hole in the curved primary mirror 10. Incident light 100 is incident on the reflecting surface of the curved secondary mirror 20 through the hole in the curved primary mirror 10. After being reflected by the curved secondary mirror 20, the incident light 100 is divided into two parts to arrive on the reflecting surface of the curved primary mirror 10 and finally is reflected and focused by the curved primary mirror 10 to point A. However, consecutive geometric curvature changes of the reflecting surfaces of the curved primary mirror 10 and the curved secondary mirror 20 are required for the reflective objective to achieve ideal phase tuning and wavefront shaping. Therefore, to obtain high-quality reflective focusing, manufacturing processes such as severe grinding and polishing are required, causing reflective objectives in the related art large in volume, heavy in weight and expensive to manufacture, and making it difficult to achieve miniaturization, integration and low-cost mass production.

In view of the above technical issues, the embodiment achieves the design of a planar transmissive metasurface lens by utilizing a planar reflective metasurface, so that the reflective lens has the advantages of being light, thin, compact and convenient for integration, and the manufacturing process of the metasurface also greatly reduces the difficulty in manufacturing the curved reflective objective in the related art, beneficial to achieving large-scale and low-cost production and assembly of the reflective objective.

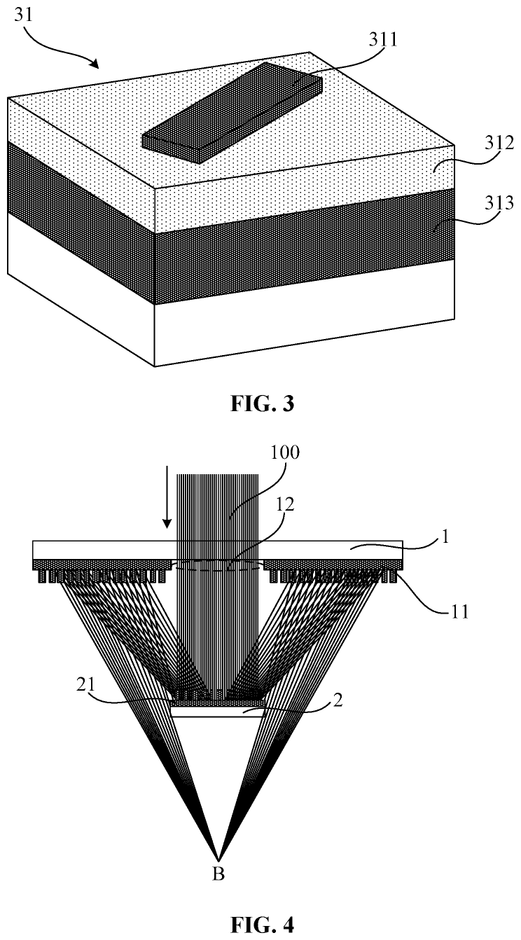

FIG. 2 is a schematic diagram illustrating a planar metasurface mirror reflects incident light according to an embodiment. FIG. 3 is a structure view of a metasurface functional unit according to an embodiment. As shown in FIG. 2, a metasurface mirror 30 is designed according to a general law of reflection. The general law of reflection can be understood as that the component of a wave vector of reflected light along the direction of a reflecting interface is equal to the vector sum of the component of a wave vector of incident light along the direction of the reflecting interface and an additional phase gradient introduced on the reflecting surface. Exemplarily, the metasurface mirror 30 has a gradient phase metasurface; in FIG. 2, dotted arrows represent horizontal mirror surface reflected light and solid arrows represent the gradient phase metasurface reflected light achieved by the metasurface mirror 30. Apparently, the gradient phase metasurface reflected light is deflected relative to the horizontal mirror surface reflected light, which is caused by the additional phase gradient introduced by the metasurface.

In an embodiment, as shown in FIG. 3, the metasurface mirror includes a plurality of metasurface functional units 31, and each metasurface functional unit 31 includes at least an anisotropic subwavelength structure 311. According to a Berry geometric phase principle, i.e., the interaction of circularly polarized light and each anisotropic subwavelength structure, the circular polarization state of the incident circularly polarized light can be reversed and meanwhile a geometric phase factor e^{-2iσφ} is introduced, where σ=±1 represents the circular polarization state of the incident light and φ is the azimuth angle of each anisotropic nanostructure on the plane. It can be seen that a continuous control of the phase, from 0 to 2π, of the incident light can be achieved through a simple change of the azimuth angle of each anisotropic subwavelength structure, and the different phases of the incident light can cause the reflected light to deflect at different angles. Then, the deflection angle of the reflected light can be adjusted through setting of the azimuth angle of the subwavelength structure 311. In an embodiment, the metasurface functional unit 31 may have a structure in which a reflective metal layer 313, a dielectric layer 312, and a subwavelength structure 311 are laminated or may have a structure with a single layer of subwavelength structure 311. The subwavelength structure 311 may be a metal subwavelength structure or a dielectric subwavelength structure, and the subwavelength structure 311 may be of a rod shape or an ellipse shape so as to achieve higher circularly polarized light conversion efficiency.

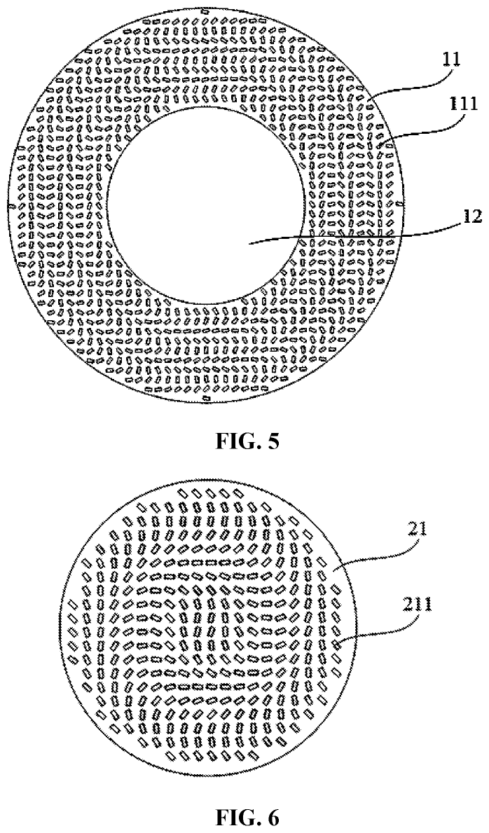

Based on the structure and principle of the metasurface mirror, the embodiment can make the entire metasurface mirror satisfy a specific phase distribution by setting the azimuth angles of subwavelength structures of multiple metasurface functional units 31 of the metasurface mirror, and use at least two metasurface mirrors to be combined into a planar reflective metasurface lens. Exemplarily, FIG. 4 is a side view of a planar reflective metasurface lens according to an embodiment. As shown in FIG. 4, the planar reflective metasurface lens includes a metasurface primary mirror 1 and a metasurface secondary mirror 2 which are disposed opposite to each other and spaced a preset distance apart. In conjunction with FIGS. 5 and 6, the metasurface primary mirror 1 includes an annular primary mirror metasurface functional structure 11 and a circular light-transmissive hole 12 encircled by the primary mirror metasurface functional structure 11. The primary mirror metasurface functional structure 11 includes a plurality of primary mirror metasurface functional units (not shown in FIG. 5, with reference to the structure of the metasurface functional unit in FIG. 3), and the primary mirror metasurface functional unit includes a primary mirror subwavelength structure 111, and the primary mirror subwavelength structures 111 are arranged on the primary mirror metasurface functional structure 11 at specific azimuth angles. The metasurface secondary mirror 2 includes a disk-shaped secondary mirror metasurface functional structure 21, the secondary mirror metasurface functional structure 21 includes a plurality of secondary mirror metasurface functional units (not shown in FIG. 6, with reference to the structure of the metasurface functional unit in FIG. 3), the secondary mirror metasurface functional unit includes a secondary mirror subwavelength structure 211, the secondary mirror subwavelength structures 211 are arranged on the secondary mirror metasurface functional structure 21 at specific azimuth angles. The secondary mirror metasurface functional structure 21 on the metasurface secondary mirror 2 is aligned with the light-transmissive hole 12 in the metasurface primary mirror 1. Therefore, the incident light 100 may be incident on the secondary mirror metasurface functional structure 21 through the light-transmissive hole 12, the incident light 100 arriving on the secondary mirror metasurface functional structure 21 may be reflected in a specific direction due to the additional phase gradient introduced by the secondary mirror subwavelength structure 211 and arrives on the primary mirror metasurface functional structure 11. Then, the additional phase gradient introduced by the primary mirror subwavelength structure 111 causes the reflected light formed through reflection by the metasurface primary mirror 1 to be focused at point B. Thus, the embodiment can achieve the design of the planar reflective metasurface lens by combining the metasurface primary mirror 1 and the metasurface secondary mirror 2.

A method for manufacturing a metasurface primary mirror, a metasurface primary mirror, a method for manufacturing a metasurface secondary mirror, and a metasurface secondary mirror are provided in the embodiments.

FIG. 7 is a flowchart of a method for manufacturing a metasurface primary mirror according to an embodiment. As shown in FIG. 7, the method for manufacturing a metasurface primary mirror includes steps described below.

In step 110, a transparent substrate is provided.

Exemplarily, a transparent substrate within a corresponding operating waveband is selected according to the material of a primary mirror metasurface functional unit pattern on the transparent substrate so as to accommodate incident light in different operating wavebands.

In step 120, a primary mirror metasurface functional unit pattern satisfying a primary mirror phase distribution is formed on the transparent substrate, such that incident light reflected by a metasurface secondary mirror onto the primary mirror is reflected and focused.

The primary mirror phase distribution may be determined according to a set parameter combined with ray optics and a general law of reflection. The set parameter includes a focal length of a system, an aperture of the metasurface primary mirror, an aperture of the metasurface secondary mirror, a distance between the metasurface primary mirror and the metasurface secondary mirror, an operating wavelength of the system, and a mapping relationship between a position where incident light arrives on the metasurface secondary mirror and a position where the incident light reflected by the metasurface secondary mirror arrives on the metasurface primary mirror. In the embodiment, the optical path of the incident light after entering the system may be determined according to the preceding set parameter, and the additional phase gradients needing to be introduced at multiple positions of the metasurface primary mirror may be determined in conjunction with the ray optics and the general law of reflection. Thus, the primary mirror phase distribution of the entire metasurface primary mirror may be determined.

The primary mirror phase distribution may also be determined according to a geometric shape of a curved primary mirror in a set curved reflective objective. The curved reflective objective includes the curved primary mirror and a curved secondary mirror. The curved primary mirror is configured to reflect and focus incident light reflected by the curved secondary mirror onto the curved primary mirror. The set curved reflective objective may be any existing curved reflective objective or any curved reflective objective configured as required. In the embodiment, according to the phase tuning effect of the curved primary mirror in the set curved reflective objective on light, the phase at the corresponding position on the metasurface primary mirror may be determined and thereby the primary mirror phase distribution of the entire metasurface primary mirror is determined. Exemplarily, the curved reflective objective may be a Schwarzschild reflective objective, and the phase distribution needing to be introduced on the metasurface primary mirror may be determined according to the direction angles of the reflected light at multiple positions of the curved primary mirror on which parallel light is normal incident and according to the general law of reflection.

According to the preceding method for manufacturing a reflective metasurface primary mirror in the embodiment, a metasurface primary mirror matching a metasurface secondary mirror in the optical system (including a planar reflective metasurface lens) can be manufactured, thus achieving the design of planar transmissive reflective lens based on the reflective metasurface, and solving the issues of being severe in manufacturing process, heavy in weight, large in volume, and difficult in miniaturization and integration of a reflective objective in the related art. In the embodiment, the curved mirror in the related art is replaced by the planar reflective metasurface which has the advantages of being light, thin, compact and convenient for integration, and the manufacturing process of the metasurface also greatly reduces the difficulty in manufacturing the curved reflective objective in the related art, beneficial to achieving large-scale and low-cost production of the reflective lens.

In an embodiment, the step in which the primary mirror metasurface functional unit pattern satisfying the primary mirror phase distribution is formed on the transparent substrates includes the following step: a primary mirror metasurface functional structure is formed in a set annular region on the transparent substrate, where the primary mirror metasurface functional structure includes a plurality of primary mirror metasurface functional units, the primary mirror metasurface functional unit includes a primary mirror subwavelength structure, a phase introduced by the primary mirror subwavelength structure satisfies the primary mirror phase distribution, the incident light arrives on the metasurface secondary mirror through a light-transmissive hole, and a central region encircled by the annular primary mirror metasurface functional structure forms the light-transmissive hole. In an embodiment, the primary mirror metasurface functional unit includes a structure in which a reflective metal layer, a dielectric layer, and a metal subwavelength structure are laminated; or the primary mirror metasurface functional unit includes a structure in which a reflective metal layer and a metal primary mirror subwavelength structure are laminated; or the primary mirror metasurface functional unit includes a structure in which a reflective metal layer and a dielectric primary mirror subwavelength structure are laminated. The primary mirror subwavelength structure is of at least one of a rod shape or an ellipse shape.

In an embodiment, the step in which the primary mirror metasurface functional structure is formed in the set annular region on the transparent substrate includes the following steps: a reflective metal layer and a dielectric layer are sequentially evaporated on the transparent substrate by using an electron beam evaporation process or a thermal evaporation process, where the reflective metal layer and the dielectric layer are laminated; electronic glue or photoresist is spin-coated on the dielectric layer; based on a Berry geometric phase principle, electronic glue or photoresist located in the set annular region is patterned by using an electron beam exposure process or photomask exposure process, such that the patterned electronic glue or photoresist satisfies the primary mirror phase distribution; a metal layer is evaporated on a surface of the dielectric layer and a surface of the patterned electronic glue or photoresist by using the electron beam evaporation process or the thermal evaporation process; the patterned electronic glue or photoresist is removed and the metal layer on the surface of the dielectric layer is retained to form the primary mirror subwavelength structure; and the reflective metal layer and the dielectric layer encircled by the set annular region are removed by using focused ion beam etching process, reactive ion beam etching process, inductively coupled plasma etching process, ion thinning process, lithography process, or laser process to form the light-transmissive hole which is flat and circular.

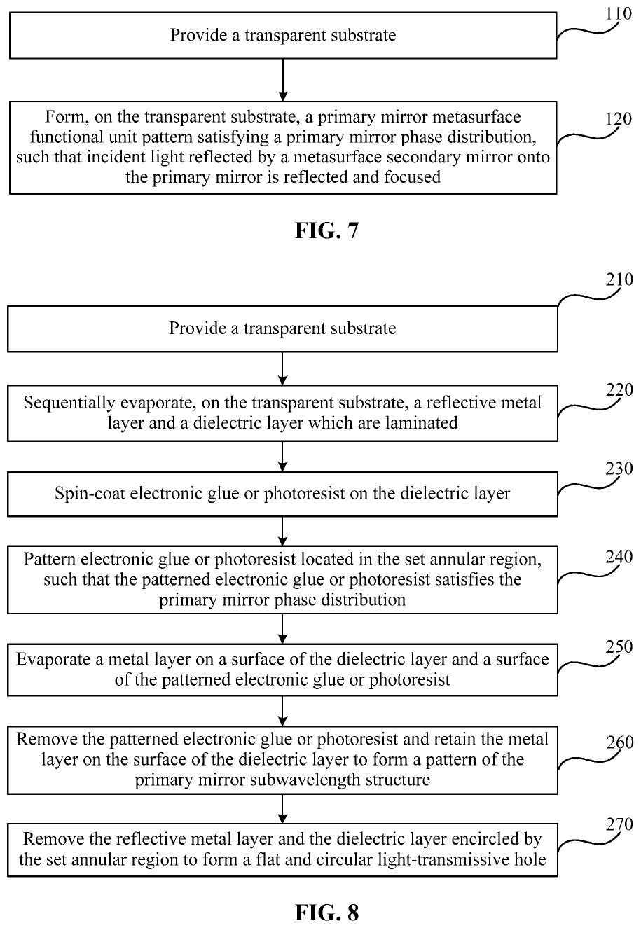

The embodiment is illustrated by using an example in which the primary mirror metasurface functional unit includes the structure in which the reflective metal layer, the dielectric layer, and the metal subwavelength structure are laminated. FIG. 8 is a flowchart of another method for manufacturing a metasurface primary mirror according to an embodiment. As shown in FIG. 8, the method for manufacturing a metasurface primary mirror includes steps described below.

In step 210, a transparent substrate is provided.

In step 220, a reflective metal layer and a dielectric layer which are laminated are sequentially evaporated on the transparent substrate by using an electron beam evaporation process or a thermal evaporation process.

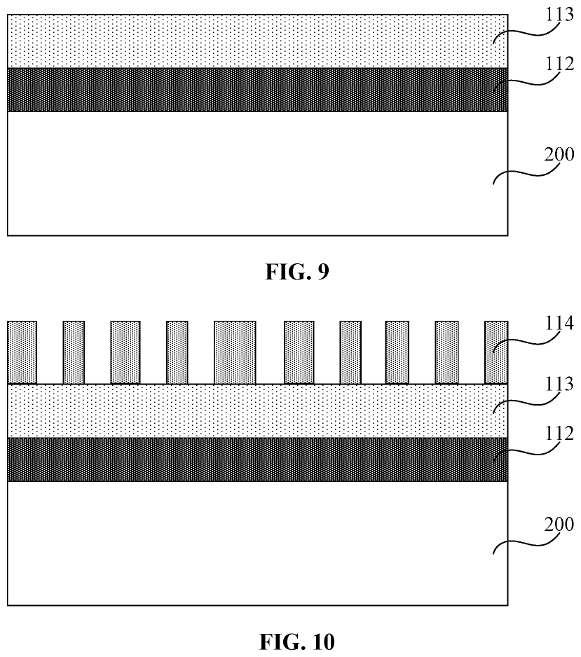

Exemplarily, referring to FIG. 9, a reflective metal layer 112 may be evaporated on a transparent substrate 200 by using the electron beam evaporation process, and then a dielectric layer 113 may be evaporated on the reflective metal layer 112 by using the thermal evaporation process. The materials of the reflective metal layer 112 and the dielectric layer 113 may be selected according to the operating waveband of the optical system. For example, in a visible near-infrared band, the reflective metal layer 112 may be made of gold, silver, aluminum, or another metal material, and the dielectric layer 113 may be made of silicon dioxide or titanium dioxide; in an infrared band, the reflective metal layer 112 may be made of gold, silver, aluminum, silicon dioxide, or titanium dioxide, and the dielectric layer 113 may be made of CaF₂, MgF₂, Ge, polytetrafluoroethylene, or another medium; in a microwave band, the reflective metal layer 112 may be made of gold, silver, aluminum, or another metal material, and the dielectric layer 113 may be made of a transparent ceramic or the like.

In step 230, electronic glue or photoresist is spin-coated on the dielectric layer.

In step 240, electronic glue or photoresist located in the set annular region is patterned by using an electron beam exposure process or a photomask exposure process, such that the patterned electronic glue or photoresist satisfies the primary mirror phase distribution.

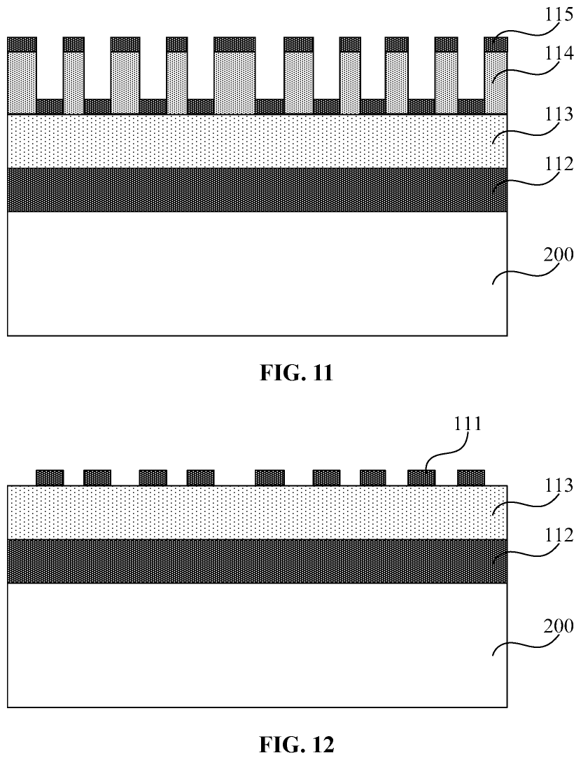

Exemplarily, referring to FIG. 10, photoresist 114 is spin-coated on the dielectric layer 113, and photoresist 114 located in a set annular region is patterned (or all of the photoresist 114 may be patterned and merely the patterned photoresist located in the set annular region satisfies a primary mirror phase distribution) by using the electron beam exposure process or the photomask exposure process, such that the patterned photoresist satisfies the primary mirror phase distribution. The set annular region is a region encircling a light-transmissive hole, and the diameter of the inner hole of the annular region may be designed according to the set size of a metasurface secondary mirror.

In the embodiment, the electronic glue should be patterned by using electron beam lithography and the photoresist should be patterned by using ultraviolet lithography. The dimensions of the subsequently formed primary mirror subwavelength structure are different for different operating wavebands, and the lithography process used in this step will also be different. For example, in a visible light band, the electron beam lithography is mostly used; in the infrared band, the ultraviolet lithography may be selected. In addition, in the microwave band, a printed circuit board technology may be adopted.

In step 250, a metal layer is evaporated on a surface of the dielectric layer and a surface of the patterned electronic glue or photoresist by using the electron beam evaporation process or the thermal evaporation process.

In step 260, the patterned electronic glue or photoresist is removed and the metal layer on the surface of the dielectric layer is retained to form a pattern of the primary mirror subwavelength structure.

Exemplarily, referring to FIG. 11, a metal layer 115 may be evaporated on the surface of a dielectric layer 113 and the surface of residual photoresist 114 (patterned photoresist) by using the electron beam evaporation process, where the opening of the residual photoresist 114 defines the shape, dimension, and azimuth angle of the primary mirror subwavelength structure formed on the surface of the dielectric layer 113. Referring to FIG. 12, the residual photoresist 114 is removed by the corresponding glue removing solution, the metal layer 115 formed on the surface of the residual photoresist 114 is simultaneously peeled off, and the metal layer on the surface of the dielectric layer 113 is retained, so that the primary mirror subwavelength structure 111 is formed.

In step 270, the reflective metal layer and the dielectric layer encircled by the set annular region are removed by using focused ion beam etching process, reactive ion beam etching process, inductively coupled plasma etching process, ion thinning process, lithography process, or laser process to form a flat and circular light-transmissive hole.

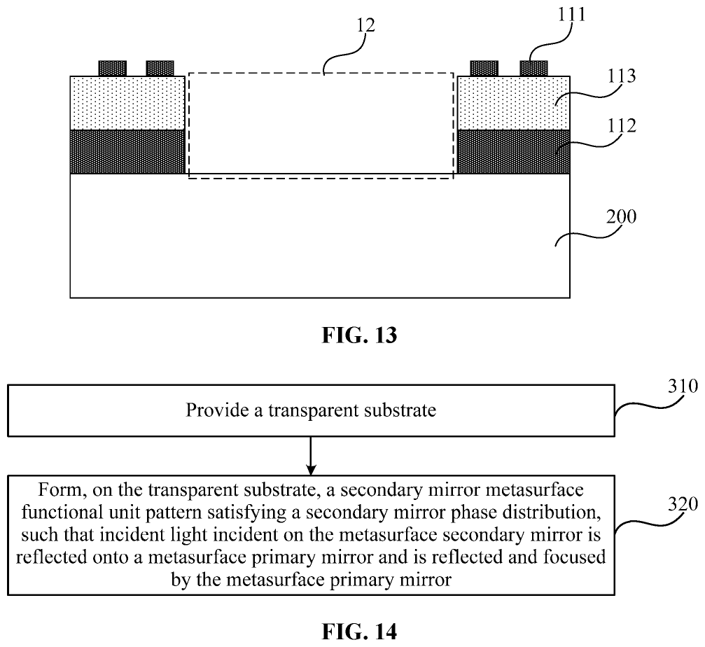

Exemplarily, referring to FIG. 13, any one of the focused ion beam etching process, reactive ion beam etching process, inductively coupled plasma etching process, ion thinning process, lithography process, or laser process may be used for removing the reflective metal layer 112 and the dielectric layer 113 in the region corresponding to the light-transmissive hole to be formed, so that a circular and flat light-transmissive hole 12 is formed, and the annular primary mirror metasurface functional structure is simultaneously formed. Thus, the manufacturing of the metasurface primary mirror is completed.

In an embodiment, the step in which the electronic glue or photoresist located in the set annular region is patterned by using the lithography process may further include a step described below.

The part of the electronic glue or photoresist located in the set annular region is patterned by using the electron beam exposure process or the photomask exposure process based on a theory of surface plasmon resonance or nanostructure scattering.

Through adjustment of the geometric dimension of the subsequently formed primary mirror subwavelength structure, high optical reflection efficiency is achieved in a required operating waveband, and thus the utilization rate of incident light is improved, the loss of the incident light is reduced, and the imaging quality of a focusing and imaging system can be improved.

An embodiment provides a metasurface primary mirror which may be manufactured by using the method for manufacturing a metasurface primary mirror of any embodiment. The metasurface primary mirror includes a transparent substrate and a primary mirror metasurface functional unit pattern located on the transparent substrate. The primary mirror metasurface functional unit pattern satisfies a primary mirror phase distribution, such that incident light reflected by a metasurface secondary mirror onto the metasurface primary mirror is reflected and focused.

Exemplarily, referring to FIGS. 5 and 13, the primary mirror metasurface functional unit pattern includes the primary mirror metasurface functional structure 11 located in a set annular region, the primary mirror metasurface functional structure 11 includes a plurality of primary mirror metasurface functional units, the primary mirror metasurface functional unit includes an anisotropic primary mirror subwavelength structure 111, and a phase introduced by the primary mirror subwavelength structure 111 satisfies a primary mirror phase distribution; and the metasurface primary mirror further includes a light-transmissive hole 12 encircled by the annular primary mirror metasurface functional structure 11, and the incident light arrives on the metasurface secondary mirror through the light-transmissive hole 12.

In an embodiment, the primary mirror metasurface functional unit includes a structure in which a reflective metal layer 112, a dielectric layer 113, and a metal subwavelength structure 111 are laminated; or the primary mirror metasurface functional unit includes a single-layer structure of a reflective metal layer, a metal primary mirror subwavelength structure, or a dielectric primary mirror subwavelength structure.

In an embodiment, for the metasurface primary mirror designed based on the Berry geometric phase principle, different phases correspond to different azimuth angles of the primary mirror subwavelength structures, i.e., the azimuth angles of the primary mirror subwavelength structures at different positions are set according to the required phase distribution, so that light can be reflected and focused by the metasurface primary mirror.

In an embodiment, the primary mirror subwavelength structure may be of at least one of a rod shape or an ellipse shape so as to achieve higher circularly polarized light conversion efficiency. Exemplarily, when the primary mirror metasurface functional unit includes the structure in which the reflective metal layer 112, the dielectric layer 113, and the metal subwavelength structure 111 are laminated, the reflective metal layer 112 and the metal subwavelength structure 111 are each made of gold, and the dielectric layer 113 is made of silicon dioxide; when the metal subwavelength structure 111 is of the rod shape. The circularly polarized light conversion efficiency can be as high as 80% in the near-infrared band.

The metasurface primary mirror provided in the embodiment and the method for manufacturing a metasurface primary mirror provided in the embodiments have the same functions and beneficial effects. For content not provided in detail in the description of the metasurface primary mirror, reference is made to the method for manufacturing a metasurface primary mirror in the embodiments. Repetition is not made herein.

Meanwhile, an embodiment further provides a method for manufacturing a metasurface secondary mirror. FIG. 14 is a flowchart of a method for manufacturing a metasurface secondary mirror according to an embodiment. As shown in FIG. 14, the method for manufacturing a metasurface secondary mirror includes steps described below.

In step 310, a transparent substrate is provided.

Exemplarily, a transparent substrate in a corresponding operating waveband is selected according to the material of a secondary mirror metasurface functional unit pattern on the transparent substrate so as to accommodate incident light in different operating wavebands.

In step 320, a secondary mirror metasurface functional unit pattern satisfying a secondary mirror phase distribution is formed on the transparent substrate, such that incident light incident on the metasurface secondary mirror is reflected onto a metasurface primary mirror and is reflected and focused by the metasurface primary mirror.

Similarly, the secondary mirror phase distribution may be determined according to a set parameter combined with ray optics and a general law of reflection. The set parameter includes a focal length of a system, an aperture of the metasurface primary mirror, an aperture of the metasurface secondary mirror, a distance between the metasurface primary mirror and the metasurface secondary mirror, an operating wavelength of the optical system, and a mapping relationship between a position where incident light arrives on the metasurface secondary mirror and a position where the incident light reflected by the metasurface secondary mirror arrives on the metasurface primary mirror. In the embodiment, the optical path of the incident light after entering the system may be determined according to the preceding set parameter, and the additional phase gradients needing to be introduced at multiple positions of the metasurface secondary mirror may be determined in conjunction with the ray optics and the general law of reflection. Thus, the secondary mirror phase distribution of the entire metasurface secondary mirror may be determined.

The secondary mirror phase distribution may also be determined according to a geometric shape of a curved secondary mirror in a set curved reflective objective. The curved reflective objective includes a curved primary mirror and the curved secondary mirror, and the curved secondary mirror is configured to reflect incident light onto the curved primary mirror such that the incident light is reflected and focused by the curved primary mirror. In the embodiment, according to the phase tuning effect of the curved secondary mirror in the set curved reflective objective on light, the phase at the corresponding position on the metasurface secondary mirror of the embodiment may be determined, and thus the secondary mirror phase distribution of the entire metasurface secondary mirror is determined. Exemplarily, the curved reflective objective may be a Schwarzschild reflective objective, and the phase distribution needing to be introduced on the metasurface secondary mirror may be determined according to the direction angles of the reflected light at multiple positions of the curved secondary mirror on which parallel light is normal incident and according to the general law of reflection.

According to the preceding method for manufacturing a metasurface secondary mirror in the embodiment, a metasurface secondary mirror matching a metasurface primary mirror in the optical system (including a planar reflective metasurface lens) can be manufactured, thus achieving the design of planar transmissive lens based on the reflective metasurface, and solving the issues of being severe in manufacturing process, heavy in weight, large in volume, and difficult in miniaturization and integration of a reflective objective in the related art. In the embodiment, the curved mirror in the related art is replaced by the planar reflective metasurface lens which has the advantages of being light, thin, compact and convenient for integration, and the manufacturing process of the metasurface also greatly reduces the difficulty in manufacturing the curved reflective objective in the related art, beneficial to achieving large-scale and low-cost production of the reflective lens.

In an embodiment, the step in which the secondary mirror metasurface functional unit pattern satisfying the secondary mirror phase distribution is formed on the transparent substrate includes the following step: a secondary mirror metasurface functional structure is formed in a set circular region on the transparent substrate, where the secondary mirror metasurface functional structure includes a plurality of secondary mirror metasurface functional units, the secondary mirror metasurface functional unit includes a secondary mirror subwavelength structure, a phase introduced by the secondary mirror subwavelength structure satisfies the secondary mirror phase distribution, and the set circular region is aligned with a light-transmissive hole in the metasurface primary mirror such that the incident light arrives on the metasurface secondary mirror through the light-transmissive hole. In an embodiment, the secondary mirror metasurface functional unit includes a structure in which a reflective metal layer, a dielectric layer, and a metal subwavelength structure are laminated; or the secondary mirror metasurface functional unit includes a reflective metal layer and a metal primary mirror subwavelength structure; or the secondary mirror metasurface functional unit includes a structure in which a reflective metal layer and a dielectric primary mirror subwavelength structure are laminated. The secondary mirror subwavelength structure is of at least one of a rod shape or an ellipse shape.

In an embodiment, the step in which the secondary mirror metasurface functional structure is formed in the set circular region on the transparent substrate includes the following steps: photoresist is spin-coated on the transparent substrate, and the part of photoresist located in the set circular region is removed; a reflective metal layer and a dielectric layer are sequentially evaporated on a surface of the transparent substrate and a surface of residual photoresist by using an electron beam evaporation process or a thermal evaporation process, and the residual photoresist is removed, where the reflective metal layer and the dielectric layer are laminated; electronic glue or photoresist is spin-coated on the dielectric layer and the exposed transparent substrate; based on a Berry geometric phase principle, electronic glue or photoresist located on the dielectric layer is patterned by using an electron beam exposure process or a photomask exposure process, such that the patterned electronic glue or photoresist satisfies the secondary mirror phase distribution; a metal layer is evaporated on a surface of the dielectric layer and a surface of the residual electronic glue or photoresist by using the electron beam evaporation process or the thermal evaporation process; and the patterned electronic glue or photoresist is removed and the metal layer on the surface of the dielectric layer is retained to form a pattern of the secondary mirror subwavelength structure.

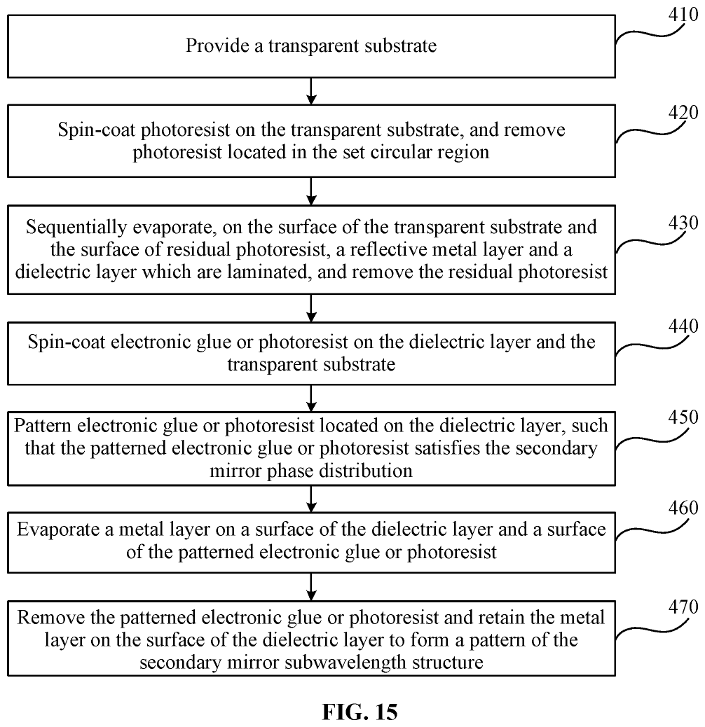

The embodiment is illustrated by using an example in which the secondary mirror metasurface functional unit includes the structure in which the reflective metal layer, the dielectric layer, and the metal subwavelength structure are laminated. FIG. 15 is a flowchart of another method for manufacturing a metasurface secondary mirror according to an embodiment. As shown in FIG. 15, the method for manufacturing a metasurface primary mirror includes steps described below.

In step 410, a transparent substrate is provided.

In step 420, photoresist is spin-coated on the transparent substrate, and photoresist located in a set circular region is removed.

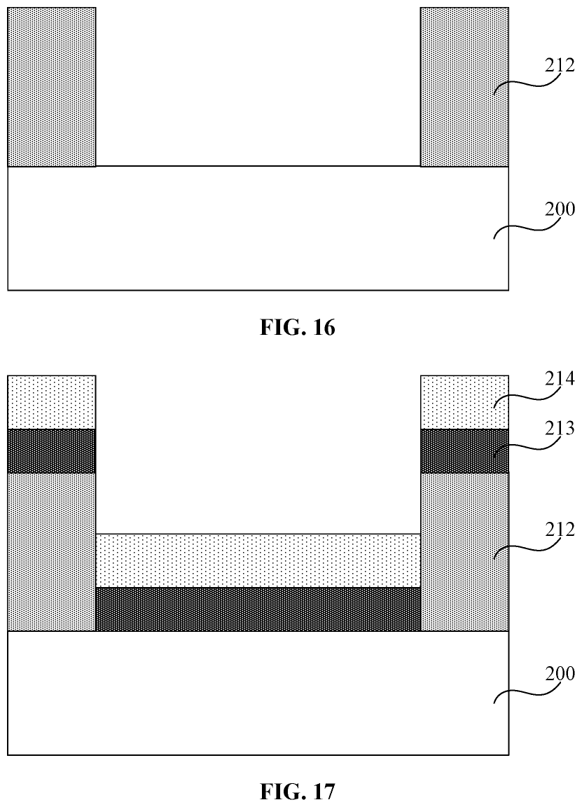

Exemplarily, referring to FIG. 16, photoresist 212 is spin-coated on a transparent substrate 200, exposed by using a mask having the same opening as the set circular region, and developed in a developing solution; the part of the photoresist 212 located in the set circular region is removed. The set circular region corresponds to a light-transmissive hole in the metasurface primary mirror.

In step 430, a reflective metal layer and a dielectric layer which are laminated are sequentially evaporated on the surface of the transparent substrate and the surface of residual photoresist by using an electron beam evaporation process or a thermal evaporation process, and the residual photoresist is removed.

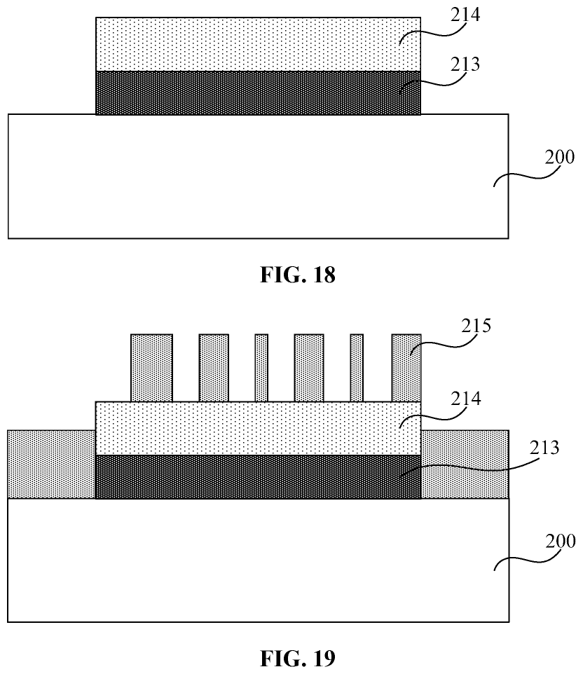

Exemplarily, referring to FIG. 17, a reflective metal layer 213 may be evaporated on the surface of the transparent substrate 200 and the surface of residual photoresist 212 by using the electron beam evaporation process, and then a dielectric layer 214 may be evaporated on the surface of the reflective metal layer 213 by using the thermal evaporation process. The materials of the reflective metal layer 213 and the dielectric layer 214 may be selected according to the operating waveband of the system. For example, in a visible near-infrared band, the reflective metal layer 213 may be made of gold, silver, aluminum, or another metal material, and the dielectric layer 214 may be made of silicon dioxide or titanium dioxide; in an infrared band, the reflective metal layer 213 may be made of gold, silver, aluminum, silicon dioxide, or titanium dioxide, and the dielectric layer 214 may be made of CaF₂, MgF₂, Ge, polytetrafluoroethylene, or another medium; in a microwave band, the reflective metal layer 213 may be made of gold, silver, aluminum, or another metal material, and the dielectric layer 214 may be made of a transparent ceramic or the like. Referring to FIG. 18, the residual photoresist 212 is removed by the corresponding glue removing solution, and a structure in which the reflective metal layer 213 and the dielectric layer 214 are laminated is formed in the set circular region.

In step 440, electronic glue or photoresist is spin-coated on the dielectric layer and the transparent substrate.

In step 450, based on a Berry geometric phase principle, electronic glue or photoresist located on the dielectric layer is patterned by using an electron beam exposure process or a photomask exposure process, such that the patterned electronic glue or photoresist satisfies the secondary mirror phase distribution.

Exemplarily, referring to FIG. 19, photoresist 215 is spin-coated on the dielectric layer 214 and the exposed transparent substrate 200. Based on the Berry geometric phase principle, the part of the photoresist 215 located in the set circular region is patterned by using a lithography process such that the patterned photoresist 215 satisfies the secondary mirror phase distribution.

In the embodiment, the electronic glue should be patterned by using the electron beam lithography, and the photoresist should be patterned by using the ultraviolet lithography. The dimensions of the subsequently formed secondary mirror subwavelength structure are different for different operating wavebands, and the lithography process used in this step will also be different. For example, in a visible light band, the electron beam lithography is mostly used; in the infrared band, the ultraviolet lithography may be selected. In addition, in the microwave band, a printed circuit board technology may be adopted.

In step 460, a metal layer is evaporated on a surface of the dielectric layer and a surface of the patterned electronic glue or photoresist by using the electron beam evaporation process or the thermal evaporation process.

In step 470, the patterned electronic glue or photoresist is removed and the metal layer on the surface of the dielectric layer is retained to form a pattern of the secondary mirror subwavelength structure.

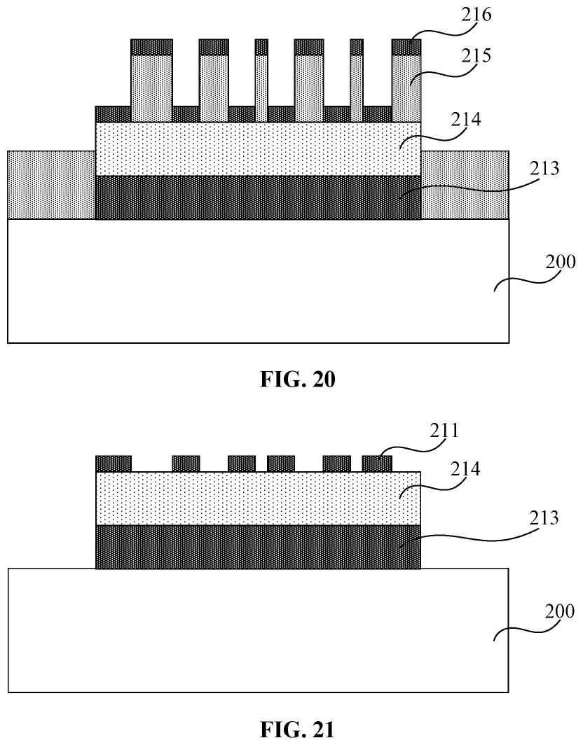

Exemplarily, referring to FIG. 20, a metal layer 216 may be evaporated on the surface of the dielectric layer 214 and the surface of residual photoresist 215 (patterned photoresist) by using the electron beam evaporation process, where the opening of the patterned photoresist 215 defines the shape, dimension, and azimuth angle of the secondary mirror subwavelength structure formed on the surface of the dielectric layer 214. Referring to FIG. 21, the residual photoresist 215 is removed by the corresponding glue removing solution, the metal layer 216 formed on the surface of the residual photoresist 114 is simultaneously peeled off, and the metal layer on the surface of the dielectric layer 113 is retained, so that the secondary mirror subwavelength structure 211 is formed and the manufacturing of the metasurface secondary mirror is completed.

In an embodiment, the step in which the electronic glue or photoresist located on the dielectric layer is patterned by using the lithography process further includes a step described below.

The electronic glue or photoresist located on the dielectric layer is patterned by using the lithography process based on the theory of surface plasmon resonance or nanostructure scattering.

Through adjustment of the geometric dimension of the subsequently formed secondary mirror subwavelength structure, high optical reflection efficiency is achieved in a required operating waveband, and thus the utilization rate of incident light is improved, the loss of the incident light is reduced, and the imaging quality of a focusing and imaging system can be improved.

An embodiment further provides a metasurface secondary mirror which may be manufactured by using the method for manufacturing a metasurface secondary mirror of any embodiment. The metasurface secondary mirror includes a transparent substrate and a secondary mirror metasurface functional unit pattern located on the transparent substrate. The secondary mirror metasurface functional unit pattern satisfies a secondary mirror phase distribution, such that incident light incident on the metasurface secondary mirror is reflected onto a metasurface primary mirror and is reflected and focused by the metasurface primary mirror.

Exemplarily, referring to FIGS. 6 and 21, the secondary mirror metasurface functional unit pattern includes a secondary mirror metasurface functional structure 21 located in a set circular region, the secondary mirror metasurface functional structure 21 includes a plurality of secondary mirror metasurface functional units, the secondary mirror metasurface functional unit includes an anisotropic secondary mirror subwavelength structure 211, and a phase introduced by the secondary mirror subwavelength structure 211 satisfies the secondary mirror phase distribution; and the secondary mirror metasurface functional structure 21 which is disk-shaped is aligned with a circular light-transmissive hole in the metasurface primary mirror, and the incident light arrives on the secondary mirror metasurface functional structure through the light-transmissive hole.

In an embodiment, the secondary mirror metasurface functional unit includes a structure in which a reflective metal layer 213, a dielectric layer 214, and a metal subwavelength structure 211 are laminated; or the secondary mirror metasurface functional unit includes a single-layer structure of a reflective metal layer 213, a metal subwavelength structure, or a dielectric subwavelength structure.

In an embodiment, for the metasurface secondary mirror designed based on the Berry geometric phase principle, different phases correspond to different azimuth angles of the secondary mirror subwavelength structures, i.e., the azimuth angles of the secondary mirror subwavelength structures at different positions are set according to the required phase distribution, so that incident light can be reflected onto the corresponding position of the metasurface primary mirror.

In an embodiment, the secondary mirror subwavelength structure may be of at least one of a rod shape or an ellipse shape so as to achieve higher circularly polarized light conversion efficiency.

The metasurface primary mirror provided in the embodiment and the method for manufacturing a metasurface primary mirror provided in the embodiments have the same functions and beneficial effects. For content not provided in detail in the description of the metasurface primary mirror, reference is made to the method for manufacturing a metasurface primary mirror. Repetition is not made herein.

In addition, an embodiment further provides an optical system including the metasurface primary mirror of any preceding embodiment and the metasurface secondary mirror of any preceding embodiment. The metasurface primary mirror and the metasurface secondary mirror are disposed opposite to each other and spaced a set distance apart, so that incident light incident on the metasurface secondary mirror is reflected onto the metasurface primary mirror and is reflected and focused by the metasurface primary mirror.

In an embodiment, the optical system may be a planar transmissive focusing and imaging system based on the reflective metasurface, including microscopes, telescopes, cameras, infrared imaging devices and the like.

In the embodiment, after the design of the optical system is completed, matlab software is used for simulating the optical path of light passing through the system. The wavelength Δλ of incident light is varied, and a focal length change Δf of the system is observed. The absolute value of Δf/Δλ is used for measuring the dispersion intensity of the system, in which the positive or negative reflects the system involving positive dispersion or negative dispersion. It is verified by simulation that the dispersion of the optical system formed by the metasurface primary mirror and the metasurface secondary mirror of the embodiment is greatly reduced compared with that of the Schwarzschild reflective objective in the related art.

According to the metasurface primary mirror, the metasurface secondary mirror, the method for manufacturing a metasurface primary mirror, the method for manufacturing a metasurface secondary mirror, and the optical system provided in the embodiments, a primary mirror metasurface functional unit pattern satisfying a primary mirror phase distribution is formed on a transparent substrate of the metasurface primary mirror, and a secondary mirror metasurface functional unit pattern satisfying a secondary mirror phase distribution is formed on a transparent substrate of the metasurface secondary mirror. Therefore, after being reflected by the metasurface secondary mirror onto the metasurface primary mirror, incident light can be reflected and focused by the metasurface primary mirror. Through the design of the metasurface primary mirror combined with the metasurface secondary mirror, the design of planar transmissive lens based on the reflective metasurface is achieved, and the issues of being severe in manufacturing process, heavy in weight, large in volume, and difficult in miniaturization and integration of a reflective objective in the related art are solved. In the embodiments, the curved mirror in the related art is replaced by the planar reflective metasurface which has the advantages of being light, thin, compact and convenient for integration, and the manufacturing process of the metasurface also greatly reduces the difficulty in manufacturing the curved reflective objective in the related art, beneficial to achieving large-scale and low-cost production of the reflective objective.

1. A method for manufacturing a metasurface primary mirror, comprising:
providing a transparent substrate; and
forming, on the transparent substrate, a primary mirror metasurface functional unit pattern satisfying a primary mirror phase distribution such that incident light reflected by a metasurface secondary mirror onto the primary mirror is reflected and focused.

2. The method for manufacturing a metasurface primary mirror of claim 1, wherein the primary mirror phase distribution is determined according to a set parameter combined with ray optics and a general law of reflection, and the set parameter comprises a focal length of a system, an aperture of the metasurface primary mirror, an aperture of the metasurface secondary mirror, a distance between the metasurface primary mirror and the metasurface secondary mirror, an operating wavelength of the system, and a mapping relationship between a position where incident light arrives on the metasurface secondary mirror and a position where the incident light reflected by the metasurface secondary mirror arrives on the metasurface primary mirror; or
the primary mirror phase distribution is determined according to a geometric shape of a curved primary mirror in a set curved reflective objective, wherein the curved reflective objective comprises the curved primary mirror and a curved secondary mirror, and the curved primary mirror is configured to reflect and focus incident light reflected by the curved secondary mirror onto the curved primary mirror.

3. The method for manufacturing a metasurface primary mirror of claim 1, wherein forming, on the transparent substrate, the primary mirror metasurface functional unit pattern satisfying the primary mirror phase distribution comprises:
forming a primary mirror metasurface functional structure in a set annular region on the transparent substrate, wherein the primary mirror metasurface functional structure comprises a plurality of primary mirror metasurface functional units, each of the plurality of primary mirror metasurface functional units comprises a primary mirror subwavelength structure, a phase introduced by the primary mirror subwavelength structure satisfies the primary mirror phase distribution, a central region encircled by the annular primary mirror metasurface functional structure forms a light-transmissive hole, and the incident light arrives on the metasurface secondary mirror through the light-transmissive hole.

4. The method for manufacturing a metasurface primary mirror of claim 3, wherein forming the primary mirror metasurface functional structure in the set annular region on the transparent substrate comprises:
sequentially evaporating a reflective metal layer and a dielectric layer on the transparent substrate by using an electron beam evaporation process or a thermal evaporation process, wherein the reflective metal layer and the dielectric layer are laminated;
spin-coating electronic glue or photoresist on the dielectric layer;
based on a Berry geometric phase principle, patterning electronic glue located in the set annular region or photoresist located in the set annular region by using an electron beam exposure process or a photomask exposure process, such that the patterned electronic glue or the patterned photoresist satisfies the primary mirror phase distribution;
evaporating a metal layer on a surface of the dielectric layer and one of a surface of the patterned electronic glue or a surface of the patterned photoresist by using the electron beam evaporation process or the thermal evaporation process;
removing the patterned electronic glue or the patterned photoresist and retaining the metal layer on the surface of the dielectric layer to form a pattern of the primary mirror subwavelength structure; and
removing reflective metal layer and dielectric layer which are encircled by the set annular region by using focused ion beam etching process, reactive ion beam etching process, inductively coupled plasma etching process, ion thinning process, lithography process, or laser process to form the light-transmissive hole which is flat and circular;
wherein patterning the electronic glue located in the set annular region or the photoresist located in the set annular region by using the electron beam exposure process or the photomask exposure process comprises:
patterning the electronic glue located in the set annular region or the photoresist located in the set annular region by using the electron beam exposure process or the photomask exposure process based on a theory of surface plasmon resonance or nanostructure scattering.

5. (canceled)

6. A metasurface primary mirror, manufactured by using the method for manufacturing a metasurface primary mirror of claim 1, comprising:
a transparent substrate; and
a primary mirror metasurface functional unit pattern located on the transparent substrate, wherein the primary mirror metasurface functional unit pattern is configured to satisfy a primary mirror phase distribution, such that incident light reflected by a metasurface secondary mirror onto the metasurface primary mirror is reflected and focused.

7. The metasurface primary mirror of claim 6, wherein the primary mirror metasurface functional unit pattern comprises a primary mirror metasurface functional structure located in a set annular region, the primary mirror metasurface functional structure comprises a plurality of primary mirror metasurface functional units, each of the plurality of primary mirror metasurface functional units comprises an anisotropic primary mirror subwavelength structure, and a phase introduced by the primary mirror subwavelength structure satisfies the primary mirror phase distribution; and
the metasurface primary mirror further comprises a light-transmissive hole encircled by the annular primary mirror metasurface functional structure, and the incident light arrives on the metasurface secondary mirror through the light-transmissive hole.

8. The metasurface primary mirror of claim 7, wherein each of the plurality of primary mirror metasurface functional units comprises a structure in which a reflective metal layer, a dielectric layer, and a metal subwavelength structure are laminated; or
each of the plurality of primary mirror metasurface functional units comprises a reflective metal layer and a metal primary mirror subwavelength structure; or
each of the plurality of primary mirror metasurface functional units comprises a structure in which a reflective metal layer and a dielectric primary mirror subwavelength structure are laminated.

9. The metasurface primary mirror of claim 7, wherein different phases of the metasurface primary mirror correspond to different azimuth angles of primary mirror subwavelength structures.

10. The metasurface primary mirror of claim 7, wherein the primary mirror subwavelength structure is an anisotropic structure which comprises at least one of a rod shape or an ellipse shape.

11. A method for manufacturing a metasurface secondary mirror, comprising:
providing a transparent substrate; and
forming, on the transparent substrate, a secondary mirror metasurface functional unit pattern satisfying a secondary mirror phase distribution, such that incident light incident on the metasurface secondary mirror is reflected onto a metasurface primary mirror and is reflected and focused by the metasurface primary mirror.

12. The method for manufacturing a metasurface secondary mirror of claim 11, wherein the secondary mirror phase distribution is determined according to a set parameter combined with ray optics and a general law of reflection, wherein the set parameter comprises a focal length of a system, an aperture of the metasurface primary mirror, an aperture of the metasurface secondary mirror, a distance between the metasurface primary mirror and the metasurface secondary mirror, an operating wavelength of the system, and a mapping relationship between a position where incident light arrives on the metasurface secondary mirror and a position where the incident light reflected by the metasurface secondary mirror arrives on the metasurface primary mirror; or
the secondary mirror phase distribution is determined according to a geometric shape of a curved secondary mirror in a set curved reflective objective, wherein the curved reflective objective comprises a curved primary mirror and the curved secondary mirror, and the curved secondary mirror is configured to reflect incident light onto the curved primary mirror such that the incident light is reflected and focused by the curved primary mirror.

13. The method for manufacturing a metasurface secondary mirror of claim 11, wherein forming, on the transparent substrate, the secondary mirror metasurface functional unit pattern satisfying the secondary mirror phase distribution comprises:
forming a secondary mirror metasurface functional structure in a set circular region on the transparent substrate, wherein the secondary mirror metasurface functional structure comprises a plurality of secondary mirror metasurface functional units, each of the plurality of secondary mirror metasurface functional units comprises a secondary mirror subwavelength structure, a phase introduced by the secondary mirror subwavelength structure satisfies the secondary mirror phase distribution, and the set circular region is configured for aligning with a light-transmissive hole in the metasurface primary mirror such that the incident light arrives on the metasurface secondary mirror through the light-transmissive hole.

14. The method for manufacturing a metasurface secondary mirror of claim 13, wherein forming the secondary mirror metasurface functional structure in the set circular region on the transparent substrate comprises:
spin-coating photoresist on the transparent substrate, and removing photoresist located in the set circular region;
sequentially evaporating a reflective metal layer and a dielectric layer on a surface of the transparent substrate and a surface of residual photoresist by using an electron beam evaporation process or a thermal evaporation process, and removing the residual photoresist, wherein the reflective metal layer and the dielectric layer are laminated;
spin-coating electronic glue or photoresist on the dielectric layer and the transparent substrate;
based on a Berry geometric phase principle, patterning electronic glue located on the dielectric layer or photoresist located on the dielectric layer by using an electron beam exposure process or a photomask exposure process, such that the patterned electronic glue or the patterned photoresist satisfies the secondary mirror phase distribution;
evaporating a metal layer on a surface of the dielectric layer and one of a surface of the patterned electronic glue or a surface of the patterned photoresist by using the electron beam evaporation process or the thermal evaporation process; and
removing the patterned electronic glue or the patterned photoresist and retaining the metal layer on the surface of the dielectric layer to form a pattern of the secondary mirror subwavelength structure;
wherein patterning the electronic glue located on the dielectric layer or the photoresist located on the dielectric layer by using the electron beam exposure process or the photomask exposure process further comprises:
patterning the electronic glue located on the dielectric layer or the photoresist located on the dielectric layer by using the electron beam exposure process or the photomask exposure process based on a theory of surface plasmon resonance or nanostructure scattering.

15. (canceled)

16. A metasurface secondary mirror, manufactured by using the method for manufacturing a metasurface secondary mirror of claim 11, comprising:
a transparent substrate; and
a secondary mirror metasurface functional unit pattern located on the transparent substrate, wherein the secondary mirror metasurface functional unit pattern is configured to satisfy a secondary mirror phase distribution, such that incident light incident on the metasurface secondary mirror is reflected onto a metasurface primary mirror and is reflected and focused by the metasurface primary mirror.

17. The metasurface secondary mirror of claim 16, wherein the secondary mirror metasurface functional unit pattern comprises a secondary mirror metasurface functional structure located in a set circular region, the secondary mirror metasurface functional structure comprises a plurality of secondary mirror metasurface functional units, each of the plurality of secondary mirror metasurface functional units comprises a secondary mirror subwavelength structure, and a phase introduced by the secondary mirror subwavelength structure satisfies the secondary mirror phase distribution; and
the secondary mirror metasurface functional structure which is disk-shaped is aligned with a circular light-transmissive hole in the metasurface primary mirror, and the incident light arrives on the secondary mirror metasurface functional structure through the light-transmissive hole.

18. The metasurface secondary mirror of claim 17, wherein each of the plurality of secondary mirror metasurface functional units comprises a structure in which a reflective metal layer, a dielectric layer, and a metal subwavelength structure are laminated; or
each of the plurality of secondary mirror metasurface functional units comprises a reflective metal layer and a metal subwavelength structure; or
each of the plurality of secondary mirror metasurface functional units comprises a structure in which a reflective metal layer and a dielectric subwavelength structure are laminated.

19. The metasurface secondary mirror of claim 17, wherein different phases of the metasurface secondary mirror correspond to different azimuth angles of secondary mirror subwavelength structures.

20. The metasurface secondary mirror of claim 17, wherein the secondary mirror subwavelength structure is an anisotropic structure which comprises at least one of a rod shape or an ellipse shape.

21. An optical system, comprising a metasurface primary mirror and a metasurface secondary mirror;
wherein the metasurface primary mirror comprises: a transparent substrate; and a primary mirror metasurface functional unit pattern located on the transparent substrate, wherein the primary mirror metasurface functional unit pattern is configured to satisfy a primary mirror phase distribution, such that incident light reflected by a metasurface secondary mirror onto the metasurface primary mirror is reflected and focused; and
wherein the metasurface secondary mirror comprises: a transparent substrate; and a secondary mirror metasurface functional unit pattern located on the transparent substrate, wherein the secondary mirror metasurface functional unit pattern is configured to satisfy a secondary mirror phase distribution, such that incident light incident on the metasurface secondary mirror is reflected onto a metasurface primary mirror and is reflected and focused by the metasurface primary mirror.

22. The optical system of claim 21, wherein the optical system is a planar transmissive focusing and imaging system based on a reflective metasurface.
